(19) United States
(12) Patent Application Publication
(10) Pub. No.: US 2026/0085403 A1
(43) Pub. Date: Mar. 26, 2026

(54) DEPOSITION-ETCH SPECIES IADF AND IEDF CONTROL FOR CARBON GAPFILL PROCESSES

(71) Applicant: Applied Materials, Inc., Santa Clara, CA (US)

(72) Inventors: Shariful Islam BHUIYAN, Santa Clara, CA (US); Abdul Aziz KHAJA, San Jose, CA (US); Peiqi WANG, Campbell, CA (US); Vamshi Krishna GADDAMEDI, Sunnyvale, CA (US); Anantha Venkataraman NAGARAJAN, Sunnyvale, CA (US)

(21) Appl. No.: 18/898,396

(22) Filed: Sep. 26, 2024

(51) Int. Cl. C23C 16/04; C23C 16/26; H01J 37/32

(52) U.S. Cl. CPC C23C 16/045; C23C 16/26; H01J 37/32146; H01J 37/32449; H01J 2237/3321; H01J 2237/3323

(57) ABSTRACT

Embodiments described herein include a device and method of for depositing a film. The method includes receiving a substrate in a process volume. The substrate includes structures thereon having varying critical dimensions. A plasma is formed in the process volume using a process gas. The plasma is formed by pulsing a combination of high frequency (HF) power and low frequency (LF) power. The film is deposited over a surface of the substrate. The film is deposited in a trench between adjacent structures, and wherein the film is formed from a precursor gas.

### BACKGROUND

### Field

Embodiments of the present disclosure generally relate to manufacture of semiconductor components and devices. More specifically, embodiments described herein provide methods for the selective deposition of carbon in a gapfill process.

### Description of the Related Art

In semiconductor processing, devices are being manufactured with continually decreasing feature dimensions. Often, features utilized to manufacture devices at these advanced technology nodes include high aspect ratio structures, and it is often beneficial to fill gaps between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc. As the width between the structures shrink, the gap between them often gets taller and narrower, making the gap more difficult to fill without the gapfill material being stuck on sidewalls and creating voids and weak seams. Furthermore, oftentimes a single device or substrate will have multiple gaps of varying widths (e.g., critical dimensions (CD)) and/or aspect ratios that will need to be filled with the gapfill material.

Conventional spin on gapfill or chemical vapor deposition (CVD) techniques often experience an overgrowth of material at the top of the gap before it has been completely filled. This can create a void or seam in the gap where the depositing material has been prematurely cut off by the overgrowth; a problem sometimes referred to as “bread-loafing.” As device geometries shrink and thermal budgets are reduced, void-free and seam-free filling of high aspect ratio spaces becomes increasingly difficult due to limitations of existing deposition processes, especially for forming gapfill material layers to concurrently fill multiple gaps with different CDs and/or aspect ratios.

Conventional PECVD gapfill processes have pattern loading issues due to various pattern densities and CDs. Conventional PECVD gapfill processes suffer from formation of ‘top hats’ where more material is deposited in the middle region than sidewall regions due to shadow effects, resulting in triangular growth. Meanwhile, state of the art spin on carbon (SOC) utilizes multiple operations of SOC, plus treatments, plus etches, to address variable CD/AR hampering throughput significantly.

Therefore, improved techniques are needed for selectively depositing carbon films, particularly for logic and DRAM applications.

### SUMMARY

In one embodiment, a method for depositing a dielectric film is disclosed. The method includes receiving a substrate in a process volume. The substrate includes structures thereon having varying critical dimensions. A plasma is formed in the process volume using a process gas. The plasma is formed by pulsing a combination of high frequency (HF) power and low frequency (LF) power. The dielectric film is deposited over a surface of the substrate. The dielectric film is deposited in a trench between adjacent structures, and wherein the dielectric film is formed from a precursor gas.

In another embodiment, a process chamber is disclosed. The process chamber includes a chamber body. The chamber body includes a lid assembly, a substrate support configured to support a substrate, a processing volume, and a controller. The substrate includes structures disposed with varying critical dimensions. The processing volume is defined by the chamber body, lid assembly, and substrate support. The controller stores instructions that, when executed, cause the controller to: form a plasma in the process volume using a process gas; and deposit a dielectric film over a surface of the substrate. The plasma is formed by pulsing a combination of high frequency (HF) power and low frequency (LF) power. The dielectric film is deposited in a trench between adjacent structures, and wherein the dielectric film is formed from a precursor gas.

In yet another embodiment, a device is disclosed. The device includes a substrate comprising a plurality of structures and a dielectric film. The plurality of structures define a plurality of trenches having varying critical dimensions (CD). The dielectric film is disposed in the trenches and includes a carbon-containing material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-sectional view of a process chamber, according to embodiments.

FIG. 2 is a diagram of a method for forming a carbon gapfill via IADF and IEDF control, according to embodiments.

FIG. 3A-3C are schematic cross-sectional view of a substrate during the method of FIG. 2, according to embodiments.

FIG. 4 is a controller, according to embodiments.

FIG. 5 is a device, according to embodiments.

FIG. 6A is a graph of the ion angular distribution function versus the ion energy distribution function for the deposition species and etchant species, according to embodiments.

FIG. 6B is a graph of the radical flux versus the ion flux for the deposition species and etchant species, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to manufacture of semiconductor components and devices. More specifically, embodiments described herein provide methods for the selective deposition of carbon in a gapfill process.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals (e.g., tungsten), metal nitrides (e.g., TiN), metal alloys, and other conductive materials, depending on the application. Substrates include, without limitation, semiconductor wafers. Substrates may be exposed to a pretreatment or post-treatment process to polish, etch, reduce, oxidize, hydroxylate, anneal, UV cure, e-beam cure and/or bake the substrate surface.

In addition to film processing directly on the surface of the substrate itself, in the present disclosure, any of the processing operations disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Carbon-based film deposition has been used to provide gapfill material layers during semiconductor processing through vapor deposition process techniques, such as CVD or plasma enhanced chemical vapor deposition (PECVD). Most vapor deposition methods, including CVD and PECVD, utilize a blanket deposition process that generally deposits more gapfill material along a top surface of a feature, where a trench between the features remains void of the gapfill material layer.

Embodiments of the present disclosure provide techniques for performing a deposition with of a high frequency radio frequency (HFRF), e.g., about 13.56 MHz to about 40 MHz, and a low frequency radio frequency (LFRF) to form a carbon gapfill layer in a trench between adjacent vertical structures having varying critical dimensions. The HFRF and LFRF can be pulsed or continuous wave (CW). The critical dimensions (CDs) are from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. Without being bound by theory, the growth profile of the carbon gapfill layer in each of the trenches may be more uniform when pulsing HFRF/LFRF as compared to conventional carbon gapfill processes.

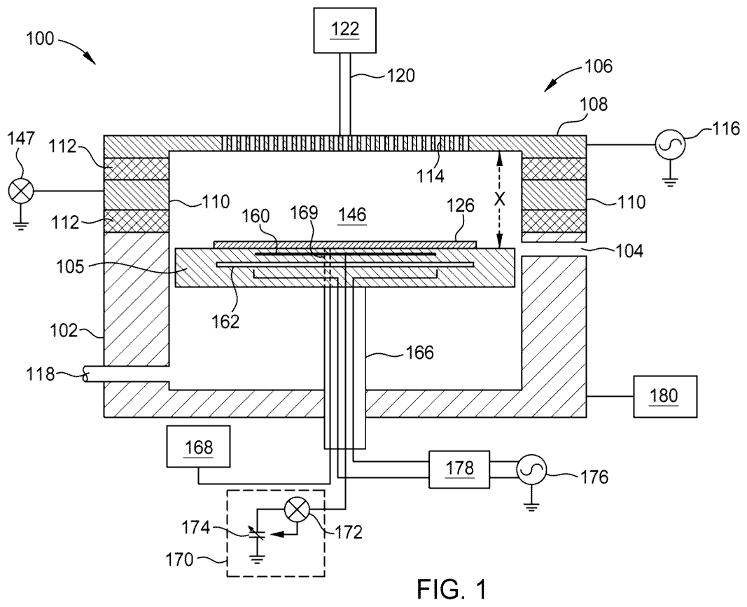

FIG. 1 is a schematic cross sectional view of a process chamber 100 configured according to various embodiments of the present disclosure. The process chamber 100 is a PECVD system, but any other process chamber may fall within the scope of the embodiments, including other plasma deposition chambers. By utilizing, in particular, a PECVD system, the cycle time of the deposition processes is reduced, resulting in higher throughput. The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define a processing volume 146 within the process chamber 100 in which a substrate 126 may be processed. The processing volume 146 may be accessed through a port 104 formed in the chamber body 102 that facilitates transfer of a substrate into and out of the processing volume 146 of the process chamber 100.

The lid assembly 106 includes a gas distributor 108, a modulation electrode 110, and insulators 112. In some embodiments, the modulation electrode 110 is optional. The insulator 112, which may be a dielectric material such as a ceramic or metal oxide, for example aluminum oxide and/or aluminum nitride. The insulator 112 contacts the modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators (e.g., annular insulators) are disposed between the gas distributor 108 and the modulation electrode 110. The modulation electrode 110 is annular and circumscribes the processing volume 146. The modulation electrode 110 is optional, and may be omitted.

Process gases (e.g., one or more precursor and one or more inert carrier gas) may be provided through the conduit 120 from a gas source 122 to be introduced into the process chamber 100. The processing gas from the conduit 120 enters the processing volume 146 through the passages 114 in the gas distributor 108 such that the processing gas is uniformly distributed in the processing volume 146. In one embodiment, the passages 114 in the gas distributor 108 may be radially distributed and gas flow to each of the passages 114 may be separately controlled to further facilitate gas uniformity within the processing volume 146.

The processing gases can be evacuated from the processing volume 146 through an outlet 118 which may be located at any convenient location along the chamber body 102. In some embodiments, the outlet 118 may be associated with a vacuum pump (not shown) fluidly coupled to the processing volume 146. The vacuum pump may be part of a gas and pressure control system of the processing chamber 100. The gas and pressure control system maintains the process volume at a pressure of about 3 Torr to about 50 Torr.

In some embodiments, which may be combined with other embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heatsink within the process chamber 100.

In some embodiments, which may be combined with other embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

The gas distributor 108 is coupled to a RF power source 116, such as a RF generator, as shown in FIG. 1. In other embodiments, the gas distributor 108 may be coupled to ground. The RF power source 116 is electrically connected to the gas distributor 108 and is configured to apply a RF potential to the gas distributor 108 to facilitate the generation of plasma in the interior processing volume 146.

The RF power source 116 may be a high frequency RF power source (“HFRF power source”) capable of generating an HFRF power (e.g., at a frequency of about 10 MHz to about 40 MHz, e.g., about 20 MHz to about 22 MHz, about 22 MHz to about 24 MHz, about 24 MHz to about 26 MHz, about 26 MHz to about 28 MHz, or about 28 MHz to about 30 MHz). The HFRF power source can be designed for use with a fixed match or automatch and can regulate the power delivered to the load, eliminating concerns about forward and reflected power. The automatch may cover multiple impedance ranges. In other embodiments, the RF power source 116 may be a low frequency RF power source (“LFRF power source”) capable of generating an LFRF power (e.g., at a frequency of about 350 kHz to about 2 MHz). The process chamber 100 includes a HFRF power source and a LFRF power source to enable pulsing of RF and LF power simultaneously.

Without being bound by theory, increasing a HFRF power source can provide an increase in the radical production rate (e.g., C₂H production rate and H production rate, when using acetylene as a precursor) and neutral production rate, thereby producing a more conformal and/or uniform carbon gapfill in trenches between one or more features, and reducing pattern loading effects.

Without being bound by theory, the LFRF power may increase the ion energy distribution function (IEDF) and decreases the ion angular distribution function (IADF), enabling increased ion flux during the generation of the plasma in the interior processing volume 146 and enabling increased ion directionality. At lower frequencies, ions experience a more constant electric field over each cycle, enabling the ions to gain more energy and uniformity and resulting in a narrower IEDF. At higher frequencies, the electric field oscillates rapidly, causing ions to experience a varying field as they traverse the sheath. This results in a broader IEDF and leads to a wider range of energies and complex energy transfer dynamics. This enables lower energy peaks, favoring a radical driven process.

At lower frequencies, ions have more time to respond to the electric field direction, resulting in a more collimated angular distribution. The ions are more likely to travel straight towards the electrode, leading to a narrow IADF. At higher frequencies, the ions experience changes in direction due to the rapidly changing electric field, which may cause ions to be deflected or scattered, broadening the IADF and reducing the directionality of the ion beam. Narrower IADF helps with directional fill/etch, while a broader IADF helps with conformal fill. Therefore, a combination of HFRF and LFRF enables an increase in the ion production and the ion directionality. Without being bound by theory, an ion driven regime (e.g., IEDF) reduces a deposition rate and decreases sheath potential. The sheath potential is the voltage difference between the plasma generated in the process chamber 100 and the substrate 126. Decreasing the sheath potential in an ion driven regime, thus, decreases the deposition rate. At higher frequencies (e.g., HFRF), the sheath responds quickly to an oscillating electric field. The rapid oscillations restricts ion movement. This rapid response typically results in a thinner sheath, as ions do not have sufficient time to penetrate deeply into the sheath before the electric field reverses direction. At lower frequencies (e.g., LFRF), the sheath has more time to respond to the oscillating field, allowing ions to further penetrate and resulting in a thicker sheath. The slower oscillation allows ions to move deeper into the sheath. The sheath thickness increases as ions travel further into the sheath, causing it to expand, as the spatial distribution of positive ions require a larger region to maintain charge balance and accommodate the electric field.

Meanwhile, a radical driven regime (e.g., IADF) increases the deposition rate, as neutral/radical regimes are driven with thermal flux, which is larger than a diffusive flux that drives the ion regime. The diffusive flux, however, enables increased uniformity in gapfill deposition between narrower critical dimension structures and wider critical dimension structures.

By pulsing HFRF and LFRF, the IEDF and IADF are tunable to improve deposition uniformity, reduce the thermal load, increase the ability for thermal management, minimize the charging effects, and enhance the plasma chemistry. A low pulsing frequency enables a broader IEDF and IADF is enabled due to longer off periods, thus enabling more ion energy loss and directional scattering. A high pulsing frequency leads to narrower IEDF and IADF due to shorter off periods, thus maintaining more consistent acceleration and directionality. Pulsing HFRF/LFRF, e.g., from 200 Hz to 10,000 Hz, enables precise control of the duration of the ion/electron behavior. Adjusting pulsing frequency and duty cycle provides a means to control the IEDF and IADF in micro- to milli-level timescales, enabling the tuning of the plasma process in various applications and for gap filling different CDs. By changing the pulsing frequency, duty cycle, and RF frequency, IADF and IEDF can be modulated in short timescales to deposit or etch the CDs and control the lifetime of ions and radicals for the process. Thus, pulsing and duty cycle can be used to modulate between the IADF and IEDF regions in a controlled manner, and to toggle between anisotropic deposition (higher ion regime) and isotropic deposition (higher radical regime) and mimic different pressure regimes.

Pulsing reduces the average power delivered to the substrate 126, minimizing thermal damage to the substrate 126. Pulsing also allows the substrate 126 and surrounding equipment to cool down, preventing overheating. Pulsing enables charge to dissipate during off periods, reducing the risk of surface charging and related defects such as arcing. Further still, the ratio of ion/neutral density enables increased control over the chemical reactions. Using continuous wave (CW) pulsing enables similar phenomena to the pulsing HFRF/LFRF.

Controlling the IADF and IEDF via RF frequency, pulsing, and duty cycle enables the imitation of different pressure regimes. For example, at low pressures, the IEDF has a narrower distribution, and higher and more consistent ion energies due to fewer collisions. Meanwhile, the IADF has a narrower angular distribution, more collimated ion trajectories, and more perpendicular ion strikes on the substrate 126. These condition can be replicated using LFRF with higher pulsing frequency and duty cycle. The duty cycle may be from about 10% to about 90%, such as about 25% to about 75%, such as about 40% to about 60%.

In another example, at high pressure, the IEDF has a broader distribution and wider range of ion energies due to frequent collisions. Meanwhile, the IADF has a broader angular distribution and more scattered ion trajectory. These conditions can be replicated using HFRF at a higher pulsing frequency and duty cycle. The duty cycle may be from about 10% to about 90%%, such as about 25% to about 75%, such as about 40% to about 60%. In further embodiments, which can be combined with other embodiments, an additional power source 147 may be added with the RF power source 116 to provide a dual RF power source to the process chamber 100. It is contemplated the modulation electrode 110 and the additional power source 147 may be omitted.

The substrate support 105 may be disposed within the process chamber 100. The substrate support 105 may support the substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 350 degrees Celsius to about 500 degrees Celsius. The substrate support 105 is a distance X from the gas distributor. The distance X is about 250 mils to about 750 mils, such as about 500 mils.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets 169 connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor and may be coupled to the variable capacitor 174 to provide further control over plasma conditions in the processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof (e.g., pulsing HFRF or continuous wave HFRF).

In operation, the substrate 126 is disposed on the substrate support 105, and process gases are flowed through the lid assembly 106 according to any desired flow plan. Electric power is coupled to the gas distributor to establish a plasma in the processing volume 146. The substrate 126 may be subjected to an electrical bias using the bias power source 176, if desired.

A controller 180 is coupled to the process chamber 100. The controller 180 controls various processing parameters of the process chamber 100, such as the gas flow rate, the temperature of the substrate 126, the position of the substrate 126, and other parameters. The controller 180 controls the various processing parameters by controlling various components of the process chamber 100, such as the RF power source 116, the additional power source 147, the tuning circuits 144 and 170, the shaft 166, the gas source 122, and other components.

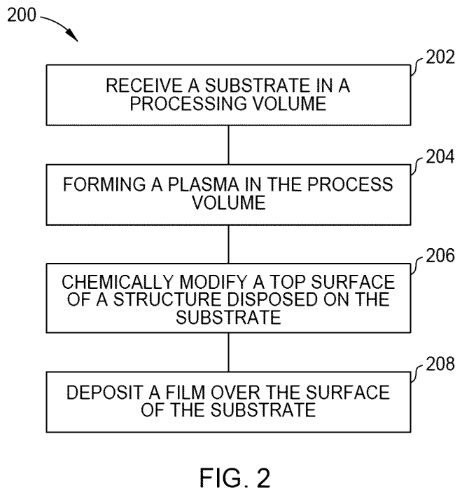

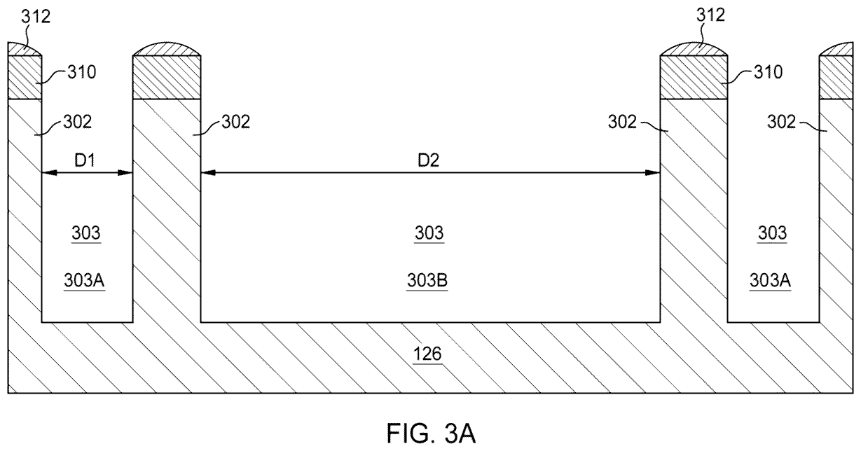

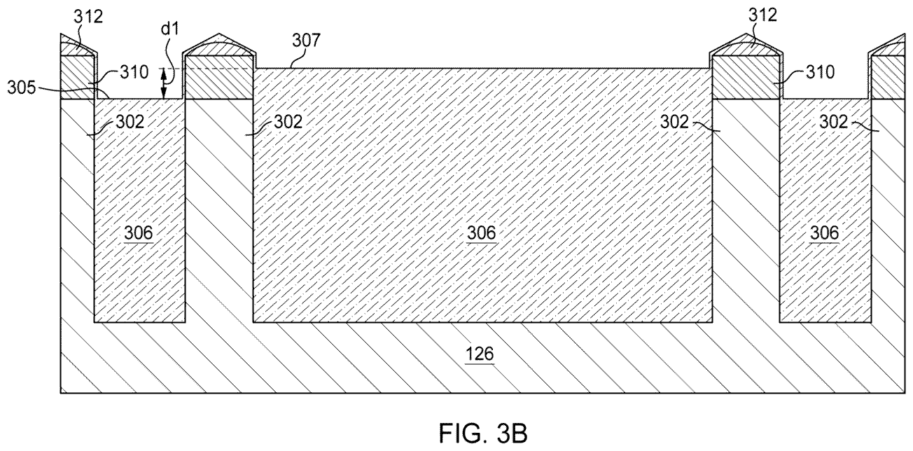

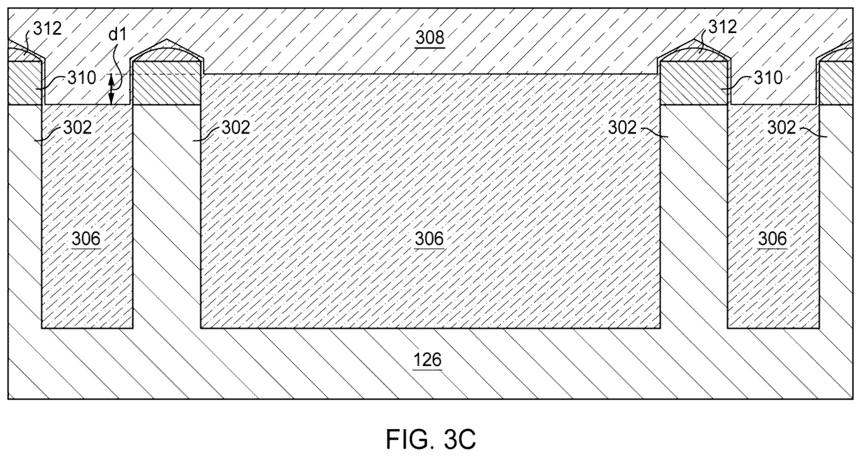

FIG. 2 is a diagram of a method 200 for forming a carbon gapfill in a device 500 via IADF and IEDF control. FIG. 3A-3C are schematic cross-sectional view of a substrate during the method 200, according to embodiments. During the method 200, the substrate 126 is maintained at a temperature of about 300° C. to about 500° C., such as about 350° C. to about 450° C.

At operation 202, a substrate 126 is received in a process volume 146. The substrate 126, as shown in FIG. 3A, includes structures 302 disposed thereon. The structures 302 define a plurality of trenches 303 in between the structures 302. The structure 302 have varying critical dimensions (CD), e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. For example, a first critical dimension D1 forming a first trench 303A may be from 3 nm to about 100 nm, while a second critical dimension D2 forming a second trench 303B is from about 150 nm to 400 nm. In some embodiments, the first trench 303B is a narrower trench and the second trench 303B is a wider trench, e.g., the second structure has a second CD D2 of 500 nm to 40 μm. The aspect ratio of the trenches 303 is about 9:1 or less.

In some embodiments, which may be combined with other embodiments. Additional materials may be disposed on a top surface of the structures 302, e.g., a first material 310 and a second material 312. The first material 310 may include a nitride material. The second material 312 may include an oxide material.

At operation 204, a plasma is formed in the process volume 146. A process gas is supplied to the process volume 146 from the gas distributor 108 and/or the gas source 122. The plasma may be formed from H₂, NH₃, N₂O, CO₂, C₂H₂, other suitable process gases, or combinations thereof. In some embodiments, a carrier gas is supplied to the process volume in combination with the process gas. The carrier gas includes argon (Ar), helium (He), nitrogen (N₂), or a combination thereof. The ratio of the carrier gas to the process gas is about 1:1 to about 1:10.

In some embodiments in which a combination of process gases are used, the combination of process gases includes an etchant gas (e.g., H₂) and a precursor gas (e.g., C₂H₂). The etchant gas and the precursor gas are co-flowed into the process volume 146 to enable etching and deposition at the same time. The etchant gas flows into the process volume 146 at about 3000 sccm to about 3500 sccm, such as about 3200 sccm to about 3300 sccm. The precursor gas flows into the process volume 146 at about 300 sccm to about 500 sccm. During operation 204, the process chamber 100 is maintained from about 3 Torr to about 50 Torr, such as about 20 Torr to about 40 Torr.

In some examples, a HF plasma is formed using HF power only. The HF power is from about 500 W to about 3000 W, such as about 1000W to about 2500W, such as about 1500 W to about 2000 W. The HF power is at a frequency of about 10 MHz to about 40 MHz, e.g., about 20 MHz to about 22 MHz, about 22 MHz to about 24 MHz, about 24 MHz to about 26 MHz, about 26 MHz to about 28 MHz, or about 28 MHz to about 30 MHz.

In other examples, a dual frequency plasma is formed using a combination of HF power and LF power. The LF power is from about 200 W to about 1500 W, such as about 500 W to about 1500W, such as about 200 W to about 1000 W. The LF power is at a frequency from 300 kHz to about 2 MHz, such as a frequency of about 350 kHz.

In yet other examples, the plasma is formed by alternating between HF power only and duel frequency plasma. The dual frequency has the highest ion energies for the ion species (e.g., C₂H₂⁺ and H₃⁺). This is due to ions absorbing LF power more effectively than HF power, hence, the increase in effective ion energy depends on the LF power.

At operation 206, as shown in FIG. 3B, a film 306 is deposited over the surface of the substrate 126. In some examples, the film 306 is a carbon gapfill. A precursor gas is supplied to the process chamber 100 to form the film 306. The precursor gas may include CO₂, C₂H₂, C₃H₆, CH₄, C₆H₆, other carbon-containing gases, or combinations thereof.

The dual frequency plasma enables directionality of the ions, as the LF power forms the ions and the HF power controls the ions. The formation and control of ions enables a reduction in the height differential d₁ between a top surface 307 of the film 306 deposited in the second trench 303B (e.g., a wider trench) and the top surface 305 of the film 306 deposited in the first trench 303A (e.g., a narrower trench). In some embodiments, the height differential d₁ is less than about 15 nm, such as less than about 10 nm, such as less than about 5 nm, such as less than 1 nm. Due to the directionality of the ions in the plasma formed in operation 204 enables the reduction of the height differential d₁ in as few as one deposition cycle, increasing throughput. Further, by modulating the LF power, dynamic duty cycle control is enabled. The frequency, wattage, flow rates, and pressure can be controlled and adjusted based on the type of process gas, precursor gas, carrier gas, and substrate utilized in the carbon gapfill. Optionally, a controller 180 of the process chamber 100 may utilize machine learning to control and adjust the frequency, wattage, flow rates, and pressure to achieve the desired deposition parameters of the carbon gapfill.

At operation 208, as shown in FIG. 3C, a planarization liner 308 is deposited over the film 306 to form a device 500. The planarization liner 308 is formed using a high Watt/HF (HW/HF) plasma and the precursor gas. The HW/HF plasma has a power from about 500 W to about 1500 W and a frequency of about 10 MHz to about 40 MHz. The HW/HF plasma has ions with lower power compared to ions in the HF plasma at 13.56 MHz, due to the smaller sheath at higher frequency. The ions in the HW/HF plasma are slower, and collide more frequently with neutrals and deviate more from normal incidence compared to ions in the HF plasma.

The method 200 further enables self-planarizing and thus reduces the number of deposition processes for increased throughput, while also resulting in high density carbon gapfill. Not to be bound by theory, but it is believed that a combination of pressure and H:C ratio provides a regime such that deposition is net positive in the CDs while net deposition is near zero on the wider pillar, thus enabling selective deposition of carbon films.

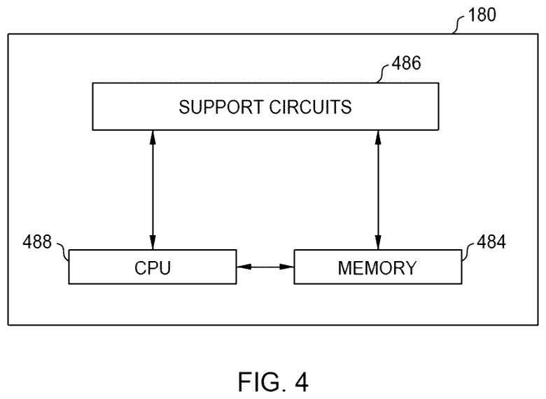

FIG. 4 is the controller 180. The controller 180 is configured to receive data or input from the process chamber 100. The controller includes a memory 484, support circuits 486, and a central processing unit (CPU) 488 (e.g., a processor) that are coupled to one another. The controller 180 controls various components of the process chamber 100 directly, or via other computers and/or controllers.

The CPU 488 is any form of general purpose computer processor that is used in an industrial setting for controlling the process chamber 100, such as a programmable logic controller (PLC), supervisory control and data acquisition (SCADA) systems, general purpose graphics processing unit (GPU), or other suitable industrial controller. The memory 484, or non-transitory computer readable medium, is one or more of a readily available memory such as random access memory (RAM), dynamic random access memory (DRAM), static RAM (SRAM), and synchronous dynamic RAM (SDRAM) (e.g., DDR1, DDR2, DDR3, DDRL3, LPDDR3, DDR4, LPDDR4, and the like)), read only memory (ROM), floppy disk, hard disk, flash drive, or any other form of digital storage, local or remote. The support circuits 486 of the controller 180 are coupled to the CPU 488 for supporting the CPU 488. The support circuits 486 include cache, power supplies, clock circuits, input/output circuitry and subsystems, and the like.

The memory 484 contains instructions that, when executed by the CPU 488, facilitates execution of the method 200. The instructions in the memory 484 are in the form of a program product such as a program that implements the method of the present disclosure. The program code of the program product may conform to any one of a number of different programming languages.

Operational parameters and operations are stored in the memory 484 as a software routine that is executed or invoked to turn the controller 180 into a specific purpose controller to control the operations of the process chamber 100. The controller 180 is configured to conduct any of the operations described herein. The instructions stored on the memory 484, when executed, cause one or more of the operations (such as operations of the method 200) described herein to be conducted in relation to the process chamber 100.

The various operations described herein can be conducted automatically using the controller 180, or can be conducted automatically or manually with certain operations conducted by a user.

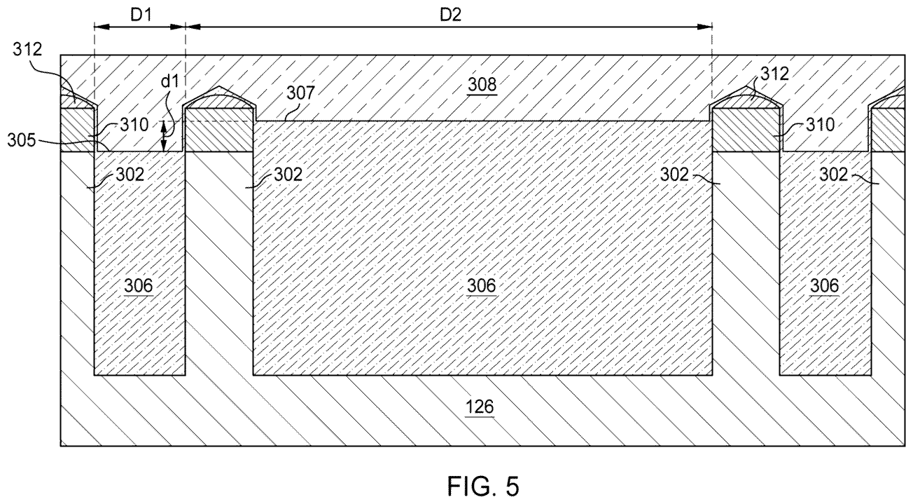

FIG. 5 is a device 500. The device 500 may be formed using method 200 and the machine learning capabilities of the controller 180. The device 500 includes a substrate 126, a first material 310 and a second material 312. The substrate 126 includes a structures 302 disposed thereon. The structures 302 define a plurality of trenches 303 in between the structures 302. The structure 302 have varying critical dimensions (CD), e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. For example, a first critical dimension D1 forming a first trench 303A (e.g., a narrower trench) may be from 3 nm to about 100 nm, while a second critical dimension D2 forming a second trench 303B is from about 150 nm to 400 nm. In some embodiments, the second trench 303B is a wider trench, e.g., the second structure has a second CD D2 of 500 nm to 40 μm.

In some embodiments, which may be combined with other embodiments, the first material 310 and the second material 312 may be disposed on a top surface of the structures 302. The first material 310 may include a nitride material. The second material 312 may include an oxide material.

A film 306 is deposited over the surface of the substrate 126. In some embodiments, the film 306 is a carbon gapfill. A precursor gas is supplied to the process chamber 100 to form the film 306. The precursor gas may include CO₂, C₂H₂, C₃H₆, CH₄, C₆H₆, other carbon-containing gases, or combinations thereof.

A distance d₁ between a top surface of the film 306 deposited in the second trench 303B and a top surface of the film 306 deposited in the first trench 303A is reduced due to the directionality of the ions in the plasma formed in operation 204. The distance d₁ is less than about 15 nm, such as less than about 10 nm, such as less than about 5 nm.

A planarization liner 308 is deposited over the film 306 to form a device 500. The planarization liner 308 is formed using a high Watt/HF (HW/HF) plasma and the precursor gas. The HW/HF plasma has a power from about 500 W to about 1500 W and a frequency of about 10 MHz to about 40 MHz.

The controller 180 is further configured to include machine learning capabilities. The controller 180 can use machine learning to optimize algorithms for calculating the processing conditions and to store instructions corresponding to the processing conditions to the memory 484. Further, the controller 180 may use metrology devices to monitor the deposition of the film 306 and adjust the processing conditions to achieve the desired deposition rate. In particular, the controller 180 can use machine learning (ML) to optimize processing conditions, such as the pressure, the gas ratio, and the HR pulsing and LF pulsing, among other parameters, in order to achieve the desired deposition rate.

The ML includes physics based simulation and experimentally validated training data. The controller 180 is trained to predict the amount of HR and LF pulsing, as well as other conditions, to predict the deposition rate, amount of radical and ion flux, and directionality of the flux to perform a gapfill process such that the desired height differential d₁ is achieved in a reduced number of deposition cycles relative to conventional approaches. In some aspects, training the controller includes training the CPU 488 to accumulate measurements from the processing chamber 100 using sensors disposed within the processing chamber 100. The sensors may measure the temperature, pressure, gas flow, power levels, deposition rates, and thickness of the films and/or planarization liner, among other processing parameters. The sensors for measuring the plasma include a langmuir probe, a hairpin probe, or an advanced retarding field analyzer.

In one embodiment, as the gapfill process (e.g., the method 200) progresses, the controller 180 continuously collects measurements from the sensors to adjust the processing parameters and measure the effects of the adjustments. Thus, by utilizing the machine learning capabilities of the controller 180, the processing conditions can be efficiently tuned using the various processing parameters above to determine the amount of radical and ion flux generated, the directionality of the flux, and the deposition rate of the process to achieve the desired height differential d₁ in a reduced number of deposition cycles. The processing conditions include, among other things, the type of source (inductively coupled plasma or capacitively coupled plasma), RF frequency, RF power, source design and geometry, pressure, temperature, gas spacing, gals flow rate, gas composition, species density, species flux, IADF, IEDF, EEDF, deposition and etch yield, frequency type (pulsed frequency, multi-source frequency, frequency source, frequency bias, synchronous/asynchronous pulsing, duty ratios, phase difference), deposition rate, deposition uniformity, deposition selectivity, and anisotropy damage.

In another embodiment, a training substrate may be used to test the processing parameters. After deposition using the training substrate, sensors may measure the height differential d₁ on the training substrate. Then, by utilizing the machine learning capabilities of the controller 180, the processing conditions can be efficiently tuned using the various processing parameters above to determine the amount of radical and ion flux generated, the directionality of the flux, and the deposition rate of the process to achieve the desired height differential d₁ in a reduced number of deposition cycles. It is contemplated that more than one training substrate may be processed successively to facilitate training of the control model.

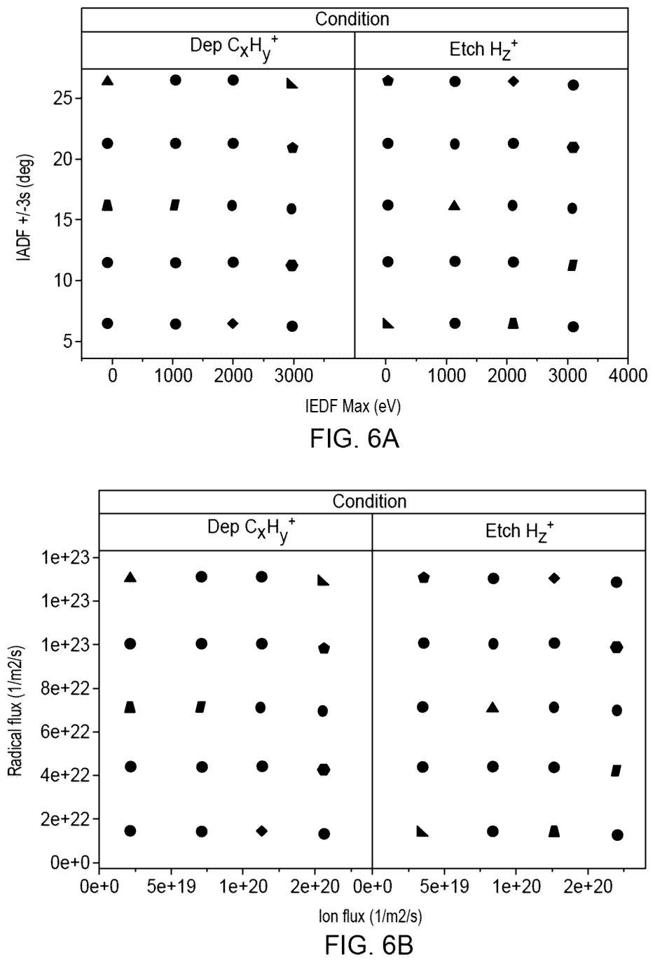

FIG. 6A is a graph of the ion angular distribution function versus the ion energy distribution function for the deposition species and etchant species. ML may be used to control the processing parameters listed above and adjust the process conditions to achieve any combination of IADF and IEDF that is desired. For example, in one embodiment, the ML may tune the processing parameters to achieve the IADF and IEDF conditions for the deposition and etch represented by the isosceles triangles. In another embodiment, the processing parameters can be tuned to achieve the IADF and IEDF conditions for the deposition and etch represented by the right triangles. In yet further embodiments, the processing parameters can be tuned to achieve the IADF and IEDF conditions for the deposition and etch represented by the pentagons, the parallelograms, the trapezoids, or the diamonds.

FIG. 6B is a graph of the radical flux versus the ion flux for the deposition species and etchant species. Similar to FIG. 6A, ML may be used to control the processing parameters listed above and adjust the process conditions to achieve any combination of radical flux and ion flux. For example, in one embodiment, the ML may tune the processing parameters can to achieve the radical flux and ion flux conditions for the deposition and etch represented by the isosceles triangles. In another embodiment, the ML may tune the processing parameters to achieve the radical flux and ion flux conditions for the deposition and etch represented by the right triangles. In yet further embodiments, the ML may tune the processing parameters to achieve the radical flux and ion flux conditions for the deposition and etch represented by the pentagons, the parallelograms, the trapezoids, or the diamonds.

While the foregoing is directed to embodiments of the present disclosure, other and further embodiments of the disclosure may be devised without departing from the basic scope thereof, and the scope thereof is determined by the claims that follow.

What is claimed is:

1. A method for depositing a film, comprising:
receiving a substrate in a process volume, the substrate comprising structures thereon having varying critical dimensions;
forming a plasma in the process volume using a process gas, wherein the plasma is formed by pulsing a combination of high frequency (HF) power and low frequency (LF) power; and
depositing the film over a surface of the substrate, wherein the film is deposited in a plurality of trenches between adjacent structures, wherein the film is formed from a precursor gas, and wherein the plurality of trenches comprise:
a narrower trench having a first critical dimension of about 150 nm to about 400 nm, wherein the film in the narrower trench has a first height;
a wider trench having a second critical dimension of about 500 nm to about 40 μm, wherein the film in the wider trench has a second height, and wherein a height differential between the top surface of the film deposited in the wider trench and the top surface of the film 306 deposited in the narrower trench is less than about 15 nm.

2. The method of claim 1, wherein forming a plasma further comprises:
supplying the process gas to the process volume, wherein the process gas comprises H₂, NH₃, N₂O, CO₂.

3. The method of claim 1, wherein depositing the film further comprises:
supplying a precursor gas to the process volume, wherein the precursor gas comprises C₂H₂, C₃H₆, CH₄, C₆H₆.

4. The method of claim 1, wherein forming a plasma further comprises:
supplying a carrier gas to the process volume, the carrier gas comprising argon, helium, hydrogen, or nitrogen.

5. The method of claim 1, wherein the HF power is from about 500W to about 3000W and at a frequency of about 10 MHz to about 40 MHz.

6. The method of claim 1, wherein the LF power is about 200 W to about 1500 W, and at a frequency from 300 kHz to about 2 MHz.

7. The method of claim 5, further comprising supplying a first process gas and a second process gas, wherein:
a flow rate of the first process gas is about 3000 sccm to about 3500 sccm; and
the flow rate of the second process gas is about 300 sccm to about 500 sccm.

8. The method of claim 1, wherein the substrate is maintained at a temperature of about 350° C. to about 450° C.

9. The method of claim 1, wherein the process volume is maintained from about 3 Torr to about 50 Torr.

10. A process chamber, comprising:
a chamber body;
a lid assembly;
a substrate support configured to support a substrate, the substrate having structures disposed with varying critical dimensions;
a processing volume defined by the chamber body, lid assembly, and substrate support; and
a controller storing instructions that, when executed, cause the controller to:
form a plasma in the process volume using a process gas, wherein the plasma is formed by pulsing a combination of high frequency (HF) power and low frequency (LF) power; and
deposit a film over a surface of the substrate, wherein the film is deposited in a plurality of trenches between adjacent structures, wherein the film is formed from a precursor gas, and wherein the plurality of trenches comprise:
a narrower trench having a first critical dimension of about 150 nm to about 400 nm, wherein the film in the narrower trench has a first height;
a wider trench having a second critical dimension of about 500 nm to about 40 μm, wherein the film in the wider trench has a second height, and wherein a height differential between the top surface of the film deposited in the wider trench and the top surface of the film 306 deposited in the narrower trench is less than about 15 nm.

11. The process chamber of claim 10, wherein the HF power is from about 500W to about 3000W and at a frequency of about 10 MHz to about 40 MHz.

12. The process chamber of claim 10, wherein the LF power is about 200 W to about 1500 W, and at a frequency from 300 kHz to about 2 MHz.

13. The process chamber of claim 10, wherein forming a plasma further comprises:
supplying the process gas to the processing volume, wherein the process gas comprises H₂, NH₃, N₂O, CO₂.

14. The process chamber of claim 13, wherein the substrate is maintained at a temperature of about 350° C. to about 450° C.

15. A device, comprising:
a substrate, comprising a plurality of structure, wherein the plurality of structures define a plurality of trenches having varying critical dimensions (CD); and
a film disposed in the plurality of trenches, the film comprising a carbon-containing material, wherein the plurality of trenches comprise:
a narrower trench having a first critical dimension of about 150 nm to about 400 nm, wherein the film in the narrower trench has a first height;
a wider trench having a second critical dimension of about 500 nm to about 40 μm, wherein the film in the wider trench has a second height, and wherein a height differential between the top surface of the film deposited in the wider trench and the top surface of the film deposited in the narrower trench is less than about 15 nm.

16. The device of claim 15, wherein the CD is from about 8 nm to about 1000 nm.

17. The device of claim 15, further comprising:
a first trench having a first CD from 3 nm to about 100 nm; and
a second trench having a second CD from of 500 nm to 40 μm.

18. The device of claim 17, wherein a distance d₁ between a top surface of the film deposited in the second trench and a top surface of the film deposited in the first trench is less than about 5 nm.

19. The device of claim 15, wherein the film is formed from a plasma formed by pulsing a combination of high frequency (HF) power and low frequency (LF) power.

20. The device of claim 19, wherein the HF power is from about 500W to about 3000W at a frequency of about 10 MHz to about 40 MHz and the LF power is about 200 W to about 1500 W at a frequency from 300 kHz to about 2 MHz.
